(19) United States
(12) Patent Application Publication
(10) Pub. No.: US 2025/0344318 A1
(43) Pub. Date: Nov. 6, 2025

(54) Printed Circuit Board Including a First Portion and a Second Portion with a Pillar Extending from the First Portion

(71) Applicant: Google LLC, Mountain View, CA (US)

(72) Inventors: Yuan-Jen Chang, Taipei (TW); Yen-Ming Hu, Hsinchu County (TW)

(21) Appl. No.: 18/865,284

(22) PCT Filed: May 19, 2022
(86) PCT No.: PCT/US2022/030056

§ 371 Date: Nov. 12, 2024

(51) Int. Cl. H05K 1/02; H05K 3/00

(52) U.S. Cl. CPC H05K 1/0284; H05K 3/0011

(57) ABSTRACT

A printed circuit board (100) for an electronic device includes a first portion (110) including an upper board (112) having a first width (w1) in a widthwise direction of the upper board (112). and a second portion (120), integrally formed with the first portion (110) as a single body. the second portion (120) including one or more pillars (122) extending vertically from the first portion (110) and disposed between a first end (114) of the upper board (112) and a second end (116) of the upper board (112) in the widthwise direction. Each of the one or more pillars (122) has a second width (w2) in the widthwise direction which is narrower than the first width (w1).

### FIELD

The disclosure relates to a printed circuit board and a printed circuit board structure including the printed circuit board (PCB). The printed circuit board structure may be implemented in an electronic device, such as a wearable computing device, smartphone, camera, and the like.

### BACKGROUND

Various methods may be utilized to accommodate electronic components such as a printed circuit board structure inside the body of an electronic device. For example, some methods include providing an interposer board that is connected to a main logic board using a connector. However, the connector has several limitations. For example, as more signals need to be carried to the main logic board, the connector must be made longer. In addition, the mating height of some connectors (e.g., a board-to-board (BTB) connector or a zero insertion force (ZIF) connector) may be limited in terms of available mating heights to select from. Connectors also require screws to fix the interposer board. Another method for accommodating a printed circuit board structure inside the body of an electronic device includes a sandwich stacked PCB design. However, such a configuration requires a precise alignment of the various components. Additionally, the manufacturing process for sandwich stacked PCBs is complex as multiple individual components must be precisely aligned when forming the sandwich stacked PCB and fastening elements such as screws are required to secure the components together.

### SUMMARY

Aspects and advantages of embodiments of the disclosure will be set forth in part in the following description, or can be learned from the description, or can be learned through practice of the example embodiments.

In one or more example embodiments, a printed circuit board includes a first portion including an upper board having a first width in a widthwise direction of the upper board, and a second portion, integrally formed with the first portion as a single body, the second portion including one or more pillars extending vertically from the first portion and disposed between a first end of the upper board and a second end of the upper board in the widthwise direction. Each of the one or more pillars has a second width in the widthwise direction which is narrower than the first width.

In some implementations of the printed circuit board, the one or more pillars include a pillar disposed at a central portion of the upper board in the widthwise direction.

In some implementations of the printed circuit board, the second portion includes a plurality of pillars including a first pillar disposed adjacent to the first end of the upper board and a second pillar disposed adjacent to the second end of the upper board. In some implementations, the plurality of pillars include a third pillar disposed between the first pillar and the second pillar in a central portion of the upper board in the widthwise direction.

In some implementations of the printed circuit board, the printed circuit board is coupleable to a main logic board such that when the printed circuit board is coupled to the main logic board, the first pillar is coupled to the main logic board at an angle which is oblique to the second pillar, and the first and second pillars are coupled to the main logic board at respective angles which are oblique to the third pillar.

In some implementations of the printed circuit board, a vertical height of each of the one or more pillars from an end of the pillar which extends vertically from the first portion to a distal end of the pillar, is less than or equal to about 3.0 mm.

In some implementations of the printed circuit board, the printed circuit board includes at least ten layers, the upper board including at least four layers of the at least ten layers, and the one or more pillars including at least six layers of the at least ten layers.

In some implementations of the printed circuit board, a distal end of each of the one or more pillars includes at least fifty pins, and the second width is less than about 9 mm.

In one or more example embodiments, an electronic device includes a body, and a printed circuit board structure disposed within the body. The printed circuit board structure includes a main logic board, and a printed circuit board. The printed circuit board includes a first portion including an upper board having a first width in a widthwise direction of the upper board, and a second portion, integrally formed with the first portion as a single body, the second portion including one or more pillars, coupled to the main logic board, extending vertically between the main logic board and the first portion and disposed between a first end of the upper board and a second end of the upper board in the widthwise direction, wherein each of the one or more pillars has a second width in the widthwise direction which is narrower than the first width.

In some implementations of the electronic device, the one or more pillars include a pillar disposed at a central portion of the upper board in the widthwise direction.

In some implementations of the electronic device, the second portion includes a plurality of pillars including a first pillar disposed adjacent to the first end of the upper board and a second pillar disposed adjacent to the second end of the upper board. In some implementations, the plurality of pillars include a third pillar disposed between the first pillar and the second pillar in a central portion of the upper board in the widthwise direction.

In some implementations of the electronic device, the first pillar is coupled to the main logic board at an angle which is oblique to the second pillar, and the first and second pillars are coupled to the main logic board at respective angles which are oblique to the third pillar.

In some implementations of the electronic device, a vertical height of each of the one or more pillars, extending from the main logic board to the first portion, is less than or equal to about 3.0 mm.

In one or more example embodiments, a method for manufacturing a printed circuit board structure, includes providing a laminated structured core including a first plurality of layers, a second plurality of layers, and one or more cores disposed between the first plurality of layers and the second plurality of layers, removing a first part of the second plurality of layers at a first location of the laminated structure core, and removing a second part of the second plurality of layers at a second location of the laminated structure core such that a part of the second plurality of layers located between the first location and the second location forms at least a portion of a pillar extending vertically from a portion of the laminated structured core including the first plurality of layers.

In some implementations, providing the laminated structured core includes providing a structured core including the first plurality of layers, applying a release layer to at least a portion of an upper surface of the structured core, and laminating the second plurality of layers onto the upper surface of the structured core having the release layer applied to the at least the portion of the upper surface of the structure core to obtain the laminated structured core.

In some implementations of the method, removing the first part of the second plurality of layers at the first location of the laminated structure core and removing the second part of the second plurality of layers at the second location of the laminated structure core, is performed by a mechanical milling process or a de-cap process.

In some implementations of the method, each of the first part of the second plurality of layers and the second part of the second plurality of layers extend to the release layer.

In some implementations, the method further includes coupling the pillar to a main logic board.

In some implementations of the method, a vertical height of the pillar, which extends from the main logic board to the portion of the laminated structured core including the first plurality of layers, is less than or equal to about 3.0 mm.

These and other features, aspects, and advantages of various embodiments of the disclosure will become better understood with reference to the following description, drawings, and appended claims. The accompanying drawings, which are incorporated in and constitute a part of this specification, illustrate example embodiments of the disclosure and, together with the description, serve to explain the related principles.

### BRIEF DESCRIPTION OF THE DRAWINGS

Detailed discussion of example embodiments directed to one of ordinary skill in the art is set forth in the specification, which makes reference to the appended drawings, in which:

FIG. 1 depicts an example printed circuit board according to one or more example embodiments of the disclosure;

FIGS. 2A-2B depict example board-to-board connectors according to one or more example embodiments of the disclosure;

FIG. 2C depicts an example printed circuit board according to one or more example embodiments of the disclosure;

FIGS. 3A-3B depict an example printed circuit board structure and pin configuration of the printed circuit board according to one or more example embodiments of the disclosure;

FIGS. 4A-4B depict an example printed circuit board structure and pin configuration of the printed circuit board according to one or more example embodiments of the disclosure;

FIGS. 5A-5B depict an example printed circuit board structure and pin configuration of the printed circuit board according to one or more example embodiments of the disclosure;

FIGS. 6A-6F depict an example method for manufacturing a printed circuit board through a milling de-cap process, according to one or more example embodiments of the disclosure;

FIGS. 7A-7F depict an example method for manufacturing a printed circuit board through a laser de-cap process, according to one or more example embodiments of the disclosure;

FIGS. 8A-8C depict an example method for manufacturing a printed circuit board through a milling process, according to one or more example embodiments of the disclosure;

FIGS. 9A-9C depict example via configurations in a planar view, according to one or more example embodiments of the disclosure;

FIGS. 10A-10D relate to example impedance simulation results for various via configurations according to one or more example embodiments of the disclosure;

FIGS. 11A-11C depict example stacked layer structures of a printed circuit board, according to one or more example embodiments of the disclosure;

FIG. 12 depicts an example cross-section of a stacked layer structure of a printed circuit board, according to one or more example embodiments of the disclosure;

FIG. 13 depicts a planar view of an example pin array configuration of a printed circuit board, according to one or more example embodiments of the disclosure;

FIG. 14 illustrates a flow diagram of an example, non-limiting method for manufacturing a laminated structure core, according to one or more example embodiments of the disclosure;

FIG. 15 illustrates a flow diagram of an example, non-limiting method for manufacturing a printed circuit board, according to one or more example embodiments of the disclosure; and

FIG. 16 depicts an example view of an electronic device having a printed circuit board structure according to one or more example embodiments of the disclosure.

### DETAILED DESCRIPTION

Reference now will be made to embodiments of the disclosure, one or more examples of which are illustrated in the drawings, wherein like reference characters denote like elements. Each example is provided by way of explanation of the disclosure and is not intended to limit the disclosure. In fact, it will be apparent to those skilled in the art that various modifications and variations can be made to disclosure without departing from the scope or spirit of the disclosure. For instance, features illustrated or described as part of one embodiment can be used with another embodiment to yield a still further embodiment. Thus, it is intended that the disclosure covers such modifications and variations as come within the scope of the appended claims and their equivalents.

Terms used herein are used to describe the example embodiments and are not intended to limit and/or restrict the disclosure. The singular forms “a,” “an” and “the” are intended to include the plural forms as well, unless the context clearly indicates otherwise. In this disclosure, terms such as “including”, “having”, “comprising”, and the like are used to specify features, numbers, steps, operations, elements, components, or combinations thereof, but do not preclude the presence or addition of one or more of the features, elements, steps, operations, elements, components, or combinations thereof.

It will be understood that, although the terms first, second, third, etc., may be used herein to describe various elements, the elements are not limited by these terms. Instead, these terms are used to distinguish one element from another element. For example, without departing from the scope of the disclosure, a first element may be termed as a second element, and a second element may be termed as a first element.

It will be understood that when an element is referred to as being “connected” to another element, the expression encompasses an example of a direct connection or direct coupling, as well as a connection or coupling with one or more other elements interposed therebetween.

The term “and/or” includes a combination of a plurality of related listed items or any item of the plurality of related listed items. For example, the scope of the expression or phrase “A and/or B” includes the item “A”, the item “B”, and the combination of items “A and B”.

In addition, the scope of the expression or phrase “at least one of A or B” is intended to include all of the following: (1) at least one of A, (2) at least one of B, and (3) at least one of A and at least one of B. Likewise, the scope of the expression or phrase “at least one of A, B, or C” is intended to include all of the following: (1) at least one of A, (2) at least one of B, (3) at least one of C, (4) at least one of A and at least one of B, (5) at least one of A and at least one of C, (6) at least one of B and at least one of C, and (7) at least one of A, at least one of B, and at least one of C.

According to example embodiments, a printed circuit board structure according to the disclosure may be coupled to a main logic board. The printed circuit board structure may be accommodated in electronic devices which have a relatively small size and/or in which space is limited. In addition, the design of the printed circuit board structure described herein may be varied according to an interior structure and/or space limitations of the electronic device as well as the number of signals needed, rather than being dependent upon a connector shape.

In some implementations, the printed circuit board structure includes a main logic board and a printed circuit board. The printed circuit board includes a first portion including an upper board having a first width in a widthwise direction of the upper board and a second portion including one or more pillars which extend or protrude vertically from the first portion and are disposed between a first end of the upper board and a second end of the upper board in the widthwise direction. The second portion is integrally formed with the first portion as a single body. Each of the one or more pillars has a second width in the widthwise direction which is narrower than the first width.

The one or more pillars have a first end which extends or protrudes vertically from the first portion and a second end (distal end) which can be coupled to the main logic board. Each of the one or more pillars are disposed between a first end of the upper board and a second end of the upper board in a widthwise direction of the upper board. The upper board has a first width in the widthwise direction and each pillar has a second width in the widthwise direction, the first width being greater (e.g., wider) than the second width. The upper board and the one or more pillars are integrally formed as a single body to form the printed circuit board, as will be discussed according to various manufacturing method disclosed herein.

In an example embodiment, the printed circuit board includes a plurality of pillars and a total width of the pillars (i.e., the second width multiplied by the number of pillars provided) is also less than the first width. In an example embodiment, the printed circuit board includes a single pillar, the appearance of the printed circuit board has a mushroom-like shape, and the single pillar may be disposed so as to extend from a central portion of the first portion (e.g., the upper board).

An example configuration of the printed circuit board structure includes a printed circuit board having a first pillar disposed adjacent to a first end of the upper board in a widthwise direction of the upper board and a second pillar disposed adjacent to a second end of the upper board in the widthwise direction. For example, the first and second pillars may be oriented in a same direction so as to be parallel to one another. For example, the first and second pillars may be aligned with one another in a length direction (which is perpendicular to the width direction and vertical (height) direction) of the upper board.

Another example configuration of the printed circuit board structure includes a printed circuit board having a first pillar disposed adjacent to a first end of the upper board in a widthwise direction of the upper board, a second pillar disposed adjacent to a second end of the upper board, and a third pillar disposed in a central portion of the upper board in the widthwise direction. For example, the first pillar may be coupled to the main logic board at an angle which is oblique to the second pillar, and the first and second pillars may be coupled to the main logic board at respective angles which are oblique to the third pillar. For example, none of the first, second, and third pillars are oriented in a same direction so as to be parallel to one another. For example, the first and second pillars may be aligned with one another in the length direction while the third pillar may be offset from (spaced apart from) the first and second pillars in the length direction.

According to example embodiments of the disclosure, the printed circuit board includes a plurality of layers. For example, in some embodiments, the printed circuit board can include ten or more layers. However, in alternative embodiments the printed circuit board can include less than ten layers. For example, the printed circuit board may include a first plurality of layers in the upper board and a second plurality of layers in the pillar. One or more core sections may be disposed between the first plurality of layers and the second plurality of layers. A width of the first plurality of layers in the upper board in the widthwise direction may be greater than a width of the second plurality of layers in the pillar.

According to example embodiments of the disclosure, the layers of the PCB (e.g., including the first plurality of layers and second plurality of layers) may include a combination of signal layers and ground (GND) layers, and various vias. The layers of the PCB may include conductive materials (e.g., copper foil) and insulative materials (e.g., dielectric materials such as prepeg).

According to example embodiments of the disclosure, the vertical height of each pillar may be any height greater than zero mm to about three mm. For example, a height of the upper board may be about 0.5 mm.

According to example embodiments of the disclosure, each pillar includes a plurality of pins to be connected to the main logic board. For example, the plurality of pins may be greater than 50 pins. For example, the plurality of pins are arranged at a bottom side or bottom face of the pillar facing the main logic board when the printed circuit board is coupled to the main logic board. For example, the plurality of pins are arranged in a plurality of rows, for example, four rows with thirteen pins in each row. The pins may be electrically connected to various components of the electronic device in which the PCB structure is disposed. In contrast to the arrangement of pins according to examples disclosed herein, a B2B connector may only have two rows, with twenty-six pins in each row, resulting in a length of the B2B connector being longer compared to the pillar disclosed herein. For example, a B2B connector having 52 pins with a pitch of 0.35 millimeters (mm) between pins has a length of about 11.35 mm and a B2B connector having 52 pins with a pitch of 0.40 mm between pins has a length of about 12.60 mm. In contrast, according to an example embodiment a length of the pillar having 52 pins arranged in an array of four rows with thirteen pins in each row, has a length of about 8 mm to 9 mm (e.g., about 8.8 mm), which is a reduction of about 23% and 30%, respectively, compared to the example B2B connectors described above.

The printed circuit board structures described herein can be manufactured according to one or more example methods of the disclosure.

In an embodiment, the method for manufacturing a printed circuit board structure includes providing a laminated structured core including a first plurality of layers, a second plurality of layers, and a core disposed between the first plurality of layers and the second plurality of layers. The method further includes removing a first part of the second plurality of layers at a first location of the laminated structure core, and removing a second part of the second plurality of layers at a second location of the laminated structure core such that a part of the second plurality of layers located between the first location and the second location forms at least a portion of a pillar extending vertically from a portion of the laminated structured core including the first plurality of layers. The method may further include coupling the pillar to a main logic board to form a printed circuit board structure. For example, the pillar may be coupled to the main logic board by a gluing method (e.g., using epoxy, soldering, an underfill, or combinations thereof).

In an embodiment, the laminated structured core may be obtained by providing a structured core including the first plurality of layers, applying a release layer to at least a portion of an upper surface of the structured core, and laminating the second plurality of layers onto the upper surface of the structured core having the release layer applied to the at least the portion of the upper surface of the structured core to obtain the laminated structured core. The first part of the second plurality of layers at the first location of the laminated structure core and the second part of the second plurality of layers at the second location of the laminated structure core may be removed by a mechanical milling process or a de-cap process. For example, each of the first part of the second plurality of layers and the second part of the second plurality of layers may be removed by applying a de-cap process so as to cut away the first and second parts of the second plurality of layers until the release layer is reached. For example, each of the first part of the second plurality of layers and the second part of the second plurality of layers may be removed by applying the milling tool so as to cut away the first and second parts of the second plurality of layers until the release layer is reached.

A vertical height of the pillar, which extends from the main logic board to the portion of the laminated structured core including the first plurality of layers, is more than 0.0 mm and less than or equal to about 3.0 mm. The vertical height of the pillar corresponds to a vertical height of each of the first part of the second plurality of layers and the second part of the second plurality of layers which are removed.

According to example embodiments of the disclosure, vertical impedance control and signal stability/quality may be improved by virtue of the structure of the example printed circuit boards disclosed herein. For example, a mismatch between an impedance value at a lower layer compared to an impedance value at an upper layer of the printed circuit board is lower than compared to an impedance value mismatch of a known connector. For example, a configuration of vias including ground vias and a signal via which are arranged in one, two, or three rows, may have less than a 5 ohm deviation for a 50 ohm impedance value, which is an acceptable range for a 10% tolerance value. In contrast, due to a limited pitch (distance between vias) of known connectors (e.g., having a pitch of 0.35 mm or 0.40 mm) the ground vias cannot be located closely to the signal via, resulting in a poorer signal integrity and an impedance deviation greater than 5 ohm.

Example embodiments of the disclosure provide several technical effects, benefits, and/or improvements in printed circuit board and electronic device (e.g., wearable computing device) technology. For example, as described above, the printed circuit board structure according to examples disclosed herein may be accommodated in electronic devices which have a small size and/or in which space is limited to accommodate electronic components. The design of the printed circuit board structure described herein may be varied according to an interior structure and/or space limitations of the electronic device as well as the number of signals needed, rather than being dependent upon a connector shape. For example, according to example embodiments of the printed circuit board structure, signal arrays may be arranged in more than two rows.

The printed circuit board structure according to examples disclosed herein can maximize a main logic board component placement area, be more flexible to the desired total number of usable signals, and be more flexible to current transmission limitations (e.g., B2B connectors are generally limited to 200 mA per signal pin). In addition, as the printed circuit board structure is integrally formed as a single body, the connection between the printed circuit board structure and main logic board is stronger than a connection between an interposer and the main logic board via a connector. Furthermore, as the printed circuit board structure is integrally formed as a single body, alignment issues are avoided as compared to stacked circuit boards which are composed of a plurality of pieces which are pieced together. Thus, the printed circuit board structure has improved reliability. According to the example embodiments disclosed herein, impedance control may be improved for high speed signals by configuring different signals/ground (GND) vias distributions vertically. Vertical plated through holes (PTHs) or laser vias can also provide GND shielding better than a B2B connector. Thus, the printed circuit board structure is less susceptible or immune to electromagnetic interference. Also, the pillar height of the printed circuit board structure according to examples disclosed herein is variable from between 0 mm to about 3.0 mm, and there is no need to be concerned with connector mating height constraints.

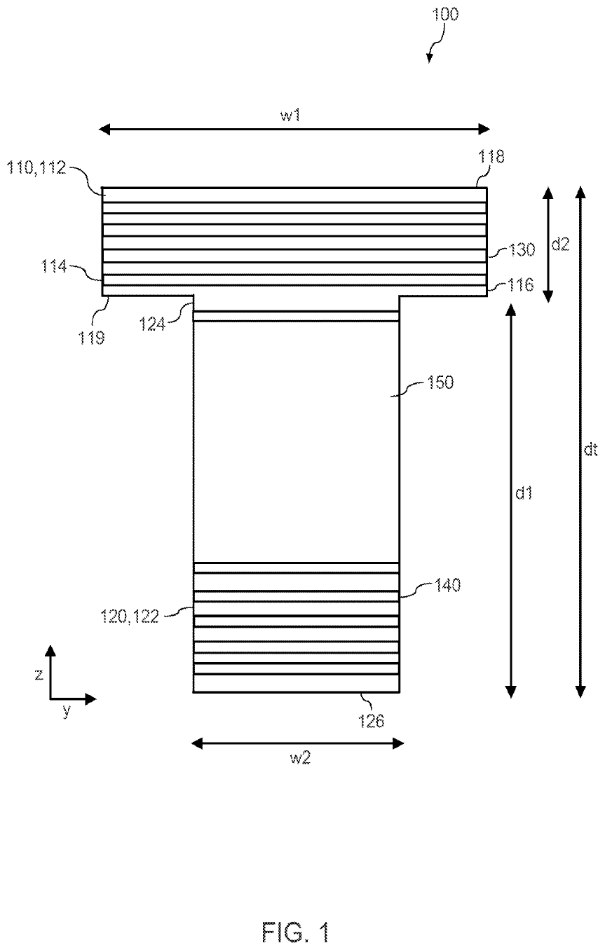

Referring now to the drawings, FIG. 1 depicts an example printed circuit board 100 according to one or more example embodiments of the disclosure. The printed circuit board 100 includes a first portion 110 including an upper board 112 having a first width w1 in a widthwise direction (e.g., y-direction) of the upper board 112 and a second portion 120 including a single pillar 122 which extends or protrudes vertically (e.g., in the z direction) from the first portion 110 and is disposed between a first end 114 of the upper board 112 and a second end 116 of the upper board 112 in the widthwise direction. The second portion 120 is integrally formed with the first portion 110 as a single body. For example, the upper board 112 and the pillar 122 are integrally formed as a single body to form the printed circuit board 100. The pillar 122 has a second width w2 in the widthwise direction which is narrower than the first width w1.

The pillar 122 has a vertical height dl which corresponds to a distance between an end 124 of the pillar 122 which extends or protrudes vertically from the first portion 110 and a distal end 126 of the pillar 122 which can be coupled to a main logic board (not shown in FIG. 1). In some embodiments, the pillar 122 may be centrally disposed between the first end 114 of the upper board 112 and the second end 116 of the upper board 112 in the widthwise direction. The upper board 112 has a vertical height d2 that spans from a first end (upper distal end) 118 of the upper board 112 and a second end (lower end 119 of the upper board 112 facing the second portion 120, along the z-direction. A total height dt of the printed circuit board 100 corresponds to a sum of the vertical heights d1 and d2.

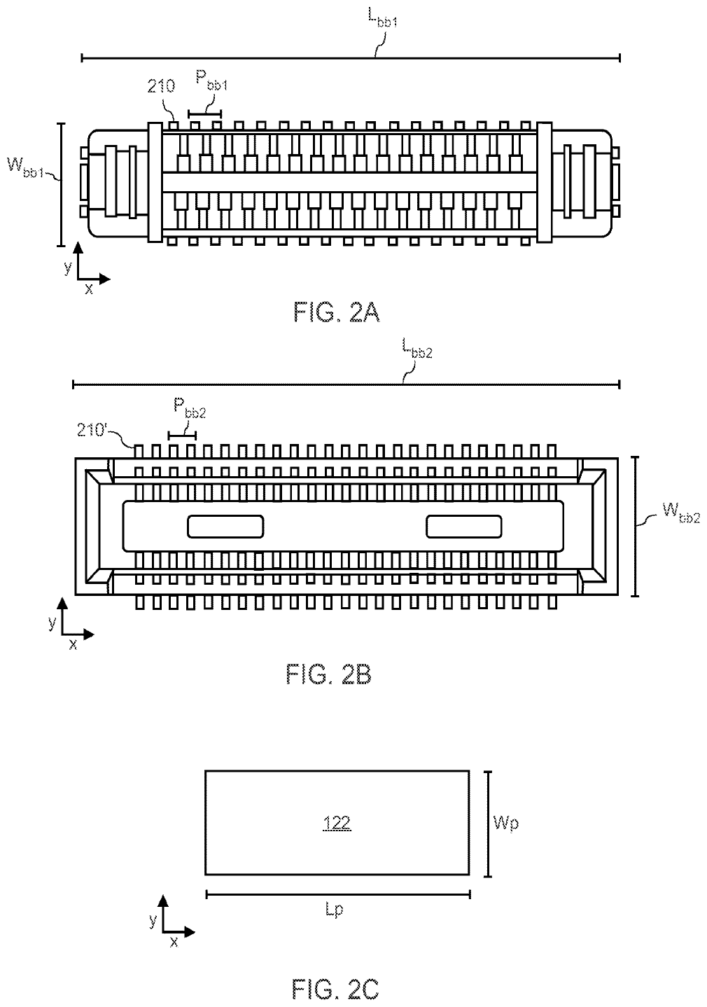

FIGS. 2A-2B depict example board-to-board connectors according to one or more example embodiments of the disclosure. FIG. 2A illustrates a first board-to-board (BTB) connector 200 while FIG. 2B illustrates a second BTB connector 200′.

Referring to FIG. 2A, the connector 200 has a width W_{bb1} and a length L_{bb1}. A pitch P_{bb1} corresponds to a distance between pins 210. As mentioned above, as more signals need to be carried to a main logic board, BTB connectors must be made longer. For example, when the number of pins is fifty or more, a length L_{bb1} of first BTB connector 200 may be about 11 to 12 mm and a width W_{bb1} of first BTB connector 200 may be about 2 mm. The area of first BTB connector 200 may be about 22 mm² to 24 mm². The pitch P_{bb1} between pins 210 may be about 0.3 mm to 0.4 mm.

Referring to FIG. 2B, the connector 200′ has a width W_{bb2} and a length L_{bb2}. A pitch P_{bb2} corresponds to a distance between pins 210′. As mentioned above, as more signals need to be carried to the main logic board, BTB connectors must be made longer. For example, when the number of pins is fifty or more, a length L_{bb2} of second BTB connector 200′ may be about 12 to 13 mm and a width W_{bb2} of second BTB connector 200′ may be about 3 to 4 mm. The area of second BTB connector 200′ may be about 36 mm² to 52 mm². The pitch P_{bb2} between pins 210′ may be about 0.4 mm.

FIG. 2C depicts an example printed circuit board according to one or more example embodiments of the disclosure. In contrast to the BTB connectors of FIGS. 2A and 2B, the pillar 122 shown in FIG. 2C according to an example embodiment of the disclosure may be made to be shorter in length. For example, referring to FIG. 2C, pillar 122 has a length Lₚ and a width Wₚ (which may correspond to width w2 from FIG. 1). As an example, when the pillar 122 includes fifty or more pins, the width Wₚ of the pillar 122 may be about 2 to 3 mm and a length Lₚ of the pillar 122 may be about 8 to about 9 mm. The area of the pillar 122 may range from about 16 mm² to about 27 mm². For instance, in some embodiments, the area of the pillar 122 may be about 23 mm². The pitch between pins (not shown in FIG. 2) provided on the pillar 122 may be between about 0.5 mm to 1 mm, for example, 0.7 mm, according to various implementations described herein. Therefore, in terms of a length reduction compared to the B2B connectors of FIGS. 2A-2B, in some implementations the pillar 122 may be about 27% to 38% shorter, for example, 23% to 30% shorter. Furthermore, some known connectors have a mating height of about 0.6 mm to about 0.8 mm. In contrast, according to example embodiments disclosed herein, the height d1 of the pillar 122 may be about 2.0 mm to about 3.0 mm, with a height d2 of the upper board being about 0.5 mm. In some implementations, the height of the pillar 122 may vary from a value more than 0 mm to about 3.0 mm.

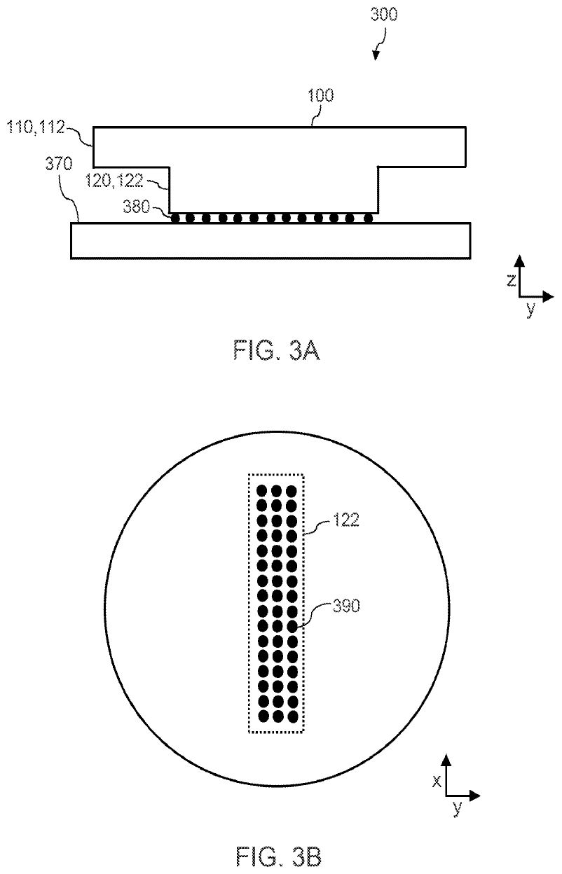

FIGS. 3A-3B depict an example printed circuit board structure and pin configuration of the printed circuit board according to one or more example embodiments of the disclosure. Referring to FIG. 3A, a printed circuit board structure 300 includes printed circuit board 100 having the first portion 110 including an upper board 112 and the second portion 120 including the single pillar 122 which extends or protrudes vertically (e.g., in the z direction) from the first portion 110. The printed circuit board structure 300 further includes a main logic board 370 on which the printed circuit board 100 is mounted or coupled to. For example, the printed circuit board 100 may be mounted or coupled to the main logic board 370 via solder balls 380. For example, the pillar 122 may be mounted to or coupled to the main logic board 370 by a gluing method (e.g., using epoxy, soldering, an underfill, or combinations thereof).

Referring to FIG. 3B, a planar view of an array of pins 390 provided on a bottom face of the pillar 122 is illustrated. In the example of FIG. 3B, the array of pins 390 includes three columns of sixteen pins for a total of 48 pins. However, it should be understood that the disclosure is not limited to this example embodiment. For instance, in alternative embodiments, the array of pins 390 may include more than 48 pins or less than 48 pins (e.g., an array of four columns with thirteen pins in each column).

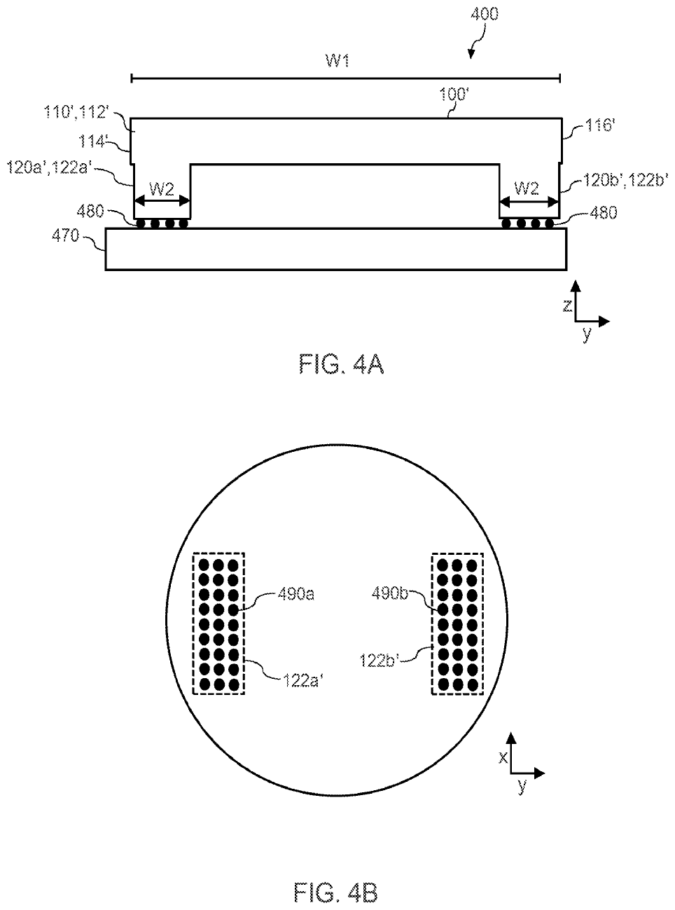

FIGS. 4A-4B depict an example printed circuit board structure and pin configuration of the printed circuit board according to one or more example embodiments of the disclosure. Referring to FIG. 4A, a printed circuit board structure 400 includes printed circuit board 100′ having the first portion 110′ including an upper board 112′ and two second portions 120a′ and 120b′ with second portion 120a including pillar 122a′ which extends or protrudes vertically (e.g., in the z direction) from the first portion 110′ and second portion 120b′ including pillar 122b′ which extends or protrudes vertically (e.g., in the z direction) from the first portion 110′. The printed circuit board structure 400 further includes a main logic board 470) on which the printed circuit board 100′ is mounted or coupled to. For example, the printed circuit board 100′ may be mounted or coupled to the main logic board 470 via solder balls 480. For example, pillar 122a′ and pillar 122b′ may be mounted to or coupled to the main logic board 470 by a gluing method (e.g., using epoxy, soldering, an underfill, or combinations thereof).

The upper board 112′ has a first width w1′ in a widthwise direction (e.g., y-direction) of the upper board 112′ and pillar 122a′ and pillar 122b′ extend or protrude vertically (e.g., in the z direction) from the first portion 110′ and are disposed between a first end 114′ of the upper board 112′ and a second end 116′ of the upper board 112′ in the widthwise direction. The second portion 120a′ and second portion 120b′ are integrally formed with the first portion 110′ as a single body. For example, the upper board 112′, pillar 122a′, and pillar 122b′ are integrally formed as a single body to form the printed circuit board 100′. Each of the pillar 122a′ and 122b′ has a second width w2′ in the widthwise direction which is narrower than (less than) the first width w1′. A total width of the pillars (i.e., two times w2′) is less than the width w1′ of the upper board 112′.

According to the example configuration of the printed circuit board structure 400 in FIG. 4A, the printed circuit board 100′ includes a first pillar (pillar 122a′) disposed adjacent to the first end 114′ of the upper board 112′ in the widthwise direction of the upper board 112′ and a second pillar (pillar 122b′) disposed adjacent to the second end 116′ of the upper board 112′ in the widthwise direction.

Referring to FIG. 4B, a planar view of an array of pins 490a provided on a bottom face of the pillar 122a′ and an array of pins 490b provided on a bottom face of the pillar 122b′, is illustrated. In the example of FIG. 4B, the array of pins 490a and the array of pins 490b each include three columns of eight pins for a total of 24 pins. It should be understood that the disclosure is not limited to this example embodiment. For instance, in alternative embodiments, the array of pins for each pillar may include more than 24 pins or less than 24 pins (e.g., an array of three columns with sixteen pins in each column, an array of four columns with thirteen pins in each column, etc.). For example, the first and second pillars (pillar 122a′ and pillar 122b′) may be oriented in a same direction so as to be parallel to one another (for example, in the x-direction). For example, as shown in FIG. 4B the first and second pillars (pillar 122a′ and pillar 122b′) may be aligned with one another in a length direction (x-direction) such that they are not offset with one another.

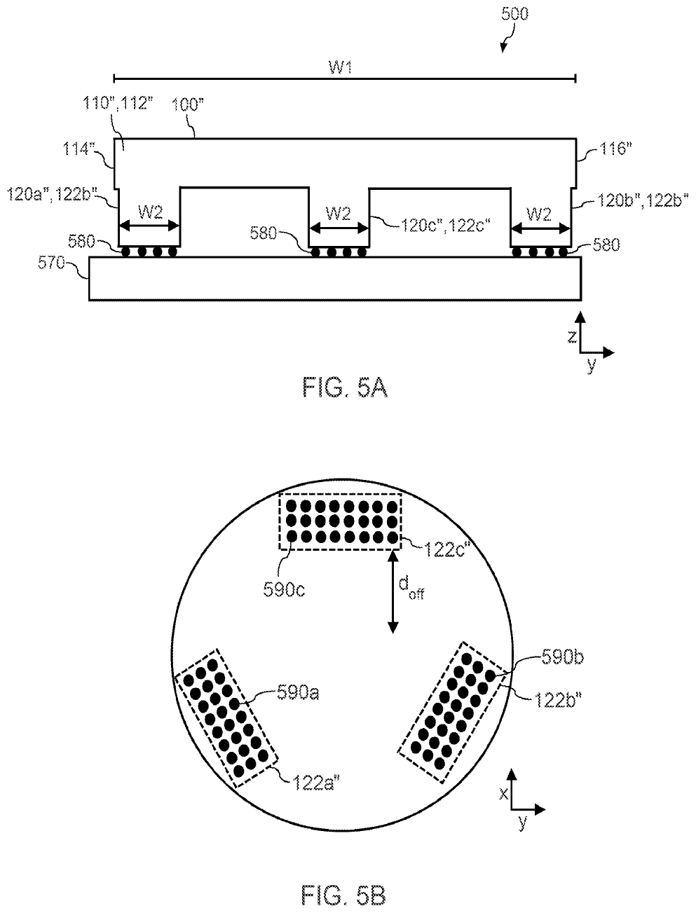

FIGS. 5A-5B depict an example printed circuit board structure and pin configuration of the printed circuit board according to one or more example embodiments of the disclosure. Referring to FIG. 5A, a printed circuit board structure 500 includes printed circuit board 100″ having the first portion 110″ including an upper board 112″ and three second portions 120a″, 120b″, and 120c′ with second portion 120a″ including pillar 122a″ which extends or protrudes vertically (e.g., in the z direction) from the first portion 110″, second portion 120b″ including pillar 122b″ which extends or protrudes vertically (e.g., in the z direction) from the first portion 110″, and second portion 120c″ including pillar 122c″ which extends or protrudes vertically (e.g., in the z direction) from the first portion 110″. The printed circuit board structure 500 further includes a main logic board 570 on which the printed circuit board 100″ is mounted or coupled to. For example, the printed circuit board 100″ may be mounted or coupled to the main logic board 570 via solder balls 580. For example, pillar 122a″, pillar 122b″, and pillar 122c″ may be mounted to or coupled to the main logic board 570 by a gluing method (e.g., using epoxy, soldering, an underfill, or combinations thereof).

The upper board 112″ has a first width w1″ in a widthwise direction (e.g., y-direction) of the upper board 112″ and pillar 122a″, pillar 122b″, and pillar 122c″ extend or protrude vertically (e.g., in the z direction) from the first portion 110″ and are disposed between a first end 114″ of the upper board 112″ and a second end 116″ of the upper board 112″ in the widthwise direction. The second portion 120a″, second portion 120b″, and second portion 120c″ are integrally formed with the first portion 110″ as a single body. For example, the upper board 112″, pillar 122a″, pillar 122b″, and pillar 122c″ are integrally formed as a single body to form the printed circuit board 100″. Pillar 122a″, pillar 122b″, and pillar 122c″ each have a second width w2″ in the widthwise direction which is narrower than (less than) the first width w1″. A total width of the pillars (i.e., three times w2″) is less than the width w1″ of the upper board 112″.

According to the example configuration of the printed circuit board structure 500 in FIG. 5A, the printed circuit board 100″ includes a first pillar (pillar 122a″) disposed adjacent to the first end 114″ of the upper board 112″ in a widthwise direction of the upper board 112″, a second pillar (pillar 122b″) disposed adjacent to the second end 116″ of the upper board 112″, and a third pillar (pillar 122c″) disposed in a central portion of the upper board in the widthwise direction.

Referring to FIG. 5B, a planar view of an array of pins 590a provided on a bottom face of the pillar 122a″, an array of pins 590b provided on a bottom face of the pillar 122b″, and an array of pins 590c provided on a bottom face of the pillar 122c″, is illustrated. In the example of FIG. 5B, the array of pins 590a, the array of pins 590b, and the array of pins 590c each include three columns of eight pins for a total of 24 pins. However, it should be understood that the disclosure disclosure is not limited to this example embodiment. For instance, in alternative embodiments, the array of pins for each pillar may include more than 24 pins or less than 24 pins (e.g., an array of three columns with sixteen pins in each column, an array of four columns with thirteen pins in each column, etc.). For example, the first pillar (pillar 122a″) may be coupled to the main logic board 570 at an angle which is oblique to the second pillar (pillar 122b″), and the first and second pillars (pillar 122a″ and pillar 122b″) may be coupled to the main logic board 570) at respective angles which are oblique to the third pillar (pillar 122c″). For example, none of the first, second, and third pillars (pillar 122a″, pillar 122b″, and pillar 122c″) may be oriented in a same direction so as to be parallel to one another (e.g., in the x-direction or y-direction). For example, the first and second pillars (pillar 122a″ and pillar 122b″) may be aligned with one another in the length direction (x-direction) while the third pillar (pillar 122c″) may be offset from (spaced apart from) the first and second pillars (pillar 122a″ and pillar 122b″) in the length direction (e.g., by distance d_{off}).

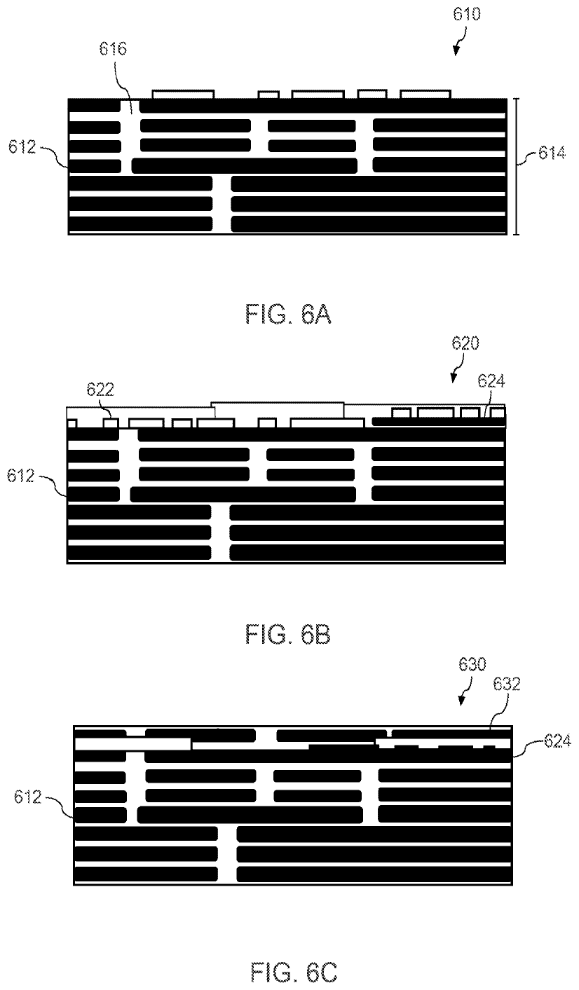

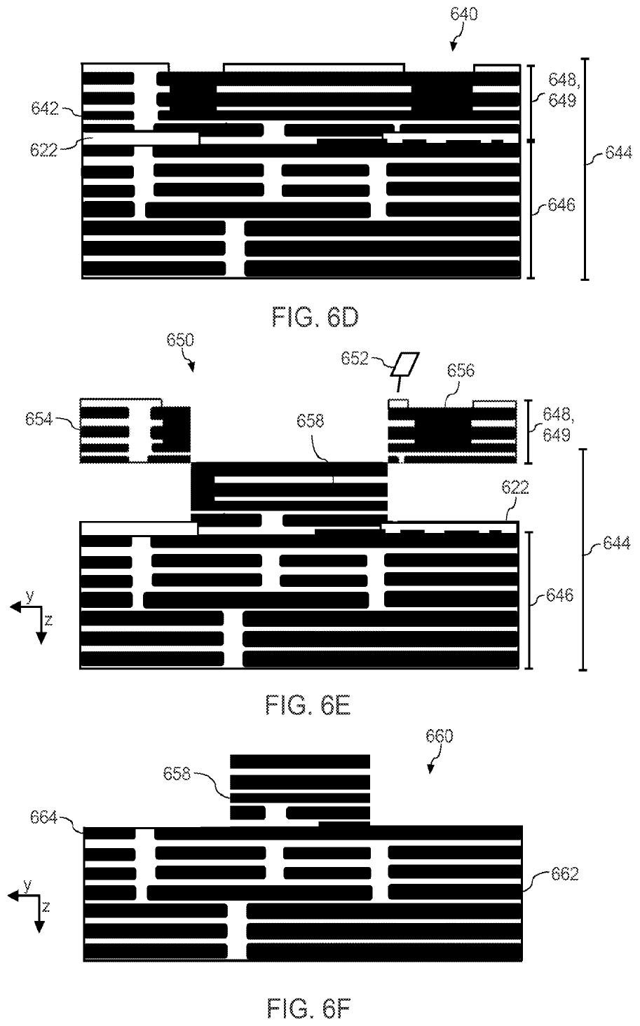

FIGS. 6A-6F depict an example method for manufacturing a printed circuit board through a milling de-cap process, according to one or more example embodiments of the disclosure.

In the example method, in FIG. 6A the method for manufacturing a printed circuit board structure includes at 610 providing a structured core 612 including a plurality of layers 614. The structured core 612 may include a plurality of vias 616, for example. The method further includes in FIG. 6B at 620 applying a release layer 622 to at least a portion of an upper surface 624 of the structured core 612, the upper surface 624 of the structured core 612 being an upper surface of the plurality of layers 614. For example, the release layer 622 may not be applied to one or more areas of the upper surface 624 of the structured core 612. The one or more areas of the upper surface 624 of the structured core 612 may correspond to location(s) of one or more areas to be formed according to the method.

The method further includes in FIG. 6C at 630 laminating one or more layers 632 onto the upper surface 624 of the structured core 612 having the release layer 622 applied to the at least the portion of the upper surface 624 of the structured core 612. In FIG. 6D at 640) additional layers 642 are laminated to complete the formation of a laminated structured core 644. The laminated structure core 644 may include a first plurality of layers 646, a second plurality of layers 648, and a core 649. For example, at least some portions of the first plurality of layers 646 may be separated from the second plurality of layers 648 and/or core 649 by the release layer 622.

The method further includes in FIG. 6E at 650 applying a milling tool 652 so as to cut away a first part 654 including the second plurality of layers 648 and core 649 and a second part 656 including the second plurality of layers 648 and core 649. For example, the milling tool 652 may be applied to cut away the first part 654 and second part 656 until the release layer 622 is reached so that the first part 654 and second part 656 can be easily removed from the release layer. The release layer 622 is a substance other than prepeg or glue and is not intended to permanently bind the layers together. After cutting away the first part 654 and second part 656, a remaining part including the second plurality of layers 648 and core 649 (which is disposed between the first part 654 and second part 656) forms at least part of a pillar 658 which extends from the first plurality of layers 646. The pillar 658 may correspond to pillar 122, or any of pillars 122a′, 122b′, 122a″, and 122b″, for example. The pillar 658 may include the second plurality of layers 648, core 649 (e.g., similar to core 150) from FIG. 1), and one or more of the first plurality of layers 646. In some implementations, pillar 658 may include the second plurality of layers 648 and core 649 and none of the first plurality of layers 646.

In FIG. 6F at 660 the method includes finalizing the printed circuit board 662 (e.g., by removing any remaining portions of the release layer 622). The printed circuit board 662 includes the pillar 658 and upper board 664, for example, having a structure similar to the printed circuit board 100. However, in other embodiments the method of FIGS. 6A-6F may be modified to form a plurality of pillars from the structured core 612 (e.g., by applying the release layer to a plurality of locations with a plurality of locations being provided between locations of the release layer corresponding to locations of the pillars to be formed by using the milling tool 652). Though not shown in FIGS. 6A-6F, the method may further include coupling the pillar 658 to a main logic board (e.g., main logic board 370) to form a printed circuit board structure (e.g., printed circuit board structure 300). For example, the pillar 658 may be coupled to a main logic board by a gluing method (e.g., using epoxy, soldering, an underfill, or combinations thereof).

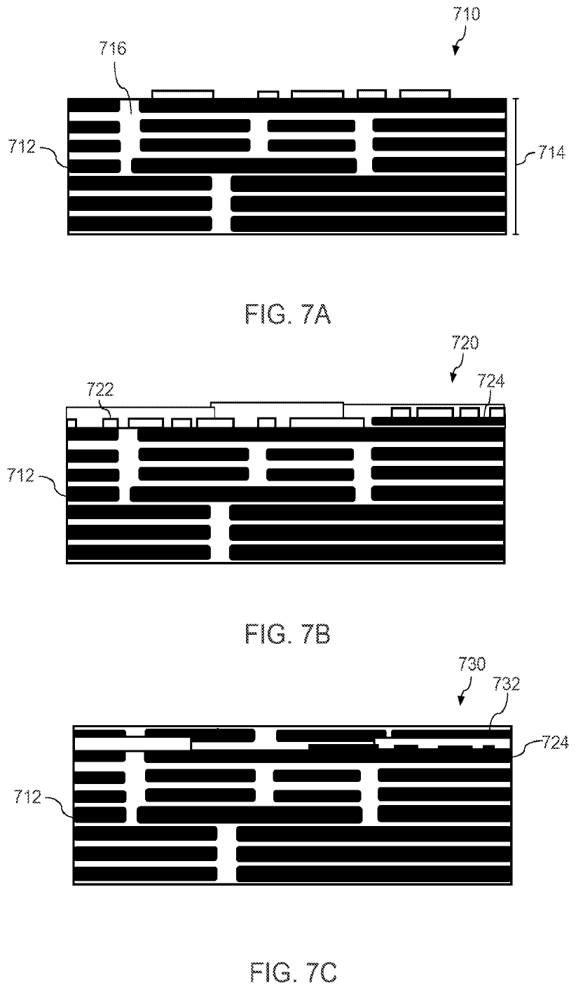

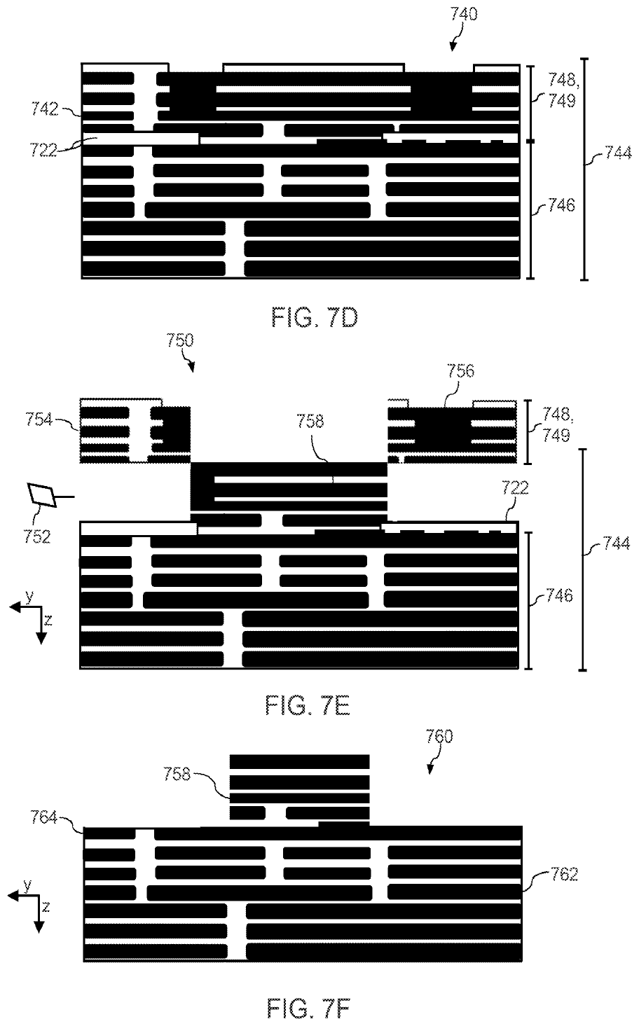

FIGS. 7A-7F depict an example method for manufacturing a printed circuit board through a laser de-cap process, according to one or more example embodiments of the disclosure. In the example method, in FIG. 7A the method for manufacturing a printed circuit board structure includes at 710 providing a structured core 712 including a plurality of layers 714. The structured core 712 may include a plurality of vias 716, for example. The method further includes in FIG. 7B at 720 applying a release layer 722 to at least a portion of an upper surface 724 of the structured core 712, the upper surface 724 of the structured core 712 being an upper surface of the plurality of layers 714. For example, the release layer 722 may not be applied to one or more areas of the upper surface 724 of the structured core 712. The one or more areas of the upper surface 724 of the structured core 712 may correspond to location(s) of one or more areas to be formed according to the method.

The method further includes in FIG. 7C at 730 laminating one or more layers 732 onto the upper surface 724 of the structured core 712 having the release layer 722 applied to the at least the portion of the upper surface 724 of the structured core 712. In FIG. 7D at 740 additional layers 742 are laminated to complete the formation of a laminated structured core 744. Referring to FIG. 7D, the laminated structure core 744 may include a first plurality of layers 746, a second plurality of layers 748, and a core 749. For example, at least some portions of the first plurality of layers 746 may be separated from the second plurality of layers 748 and/or core 749 by the release layer 722.

The method further includes in FIG. 7E at 750 applying a laser tool 752 so as to cut away a first part 754 including the second plurality of layers 748 and core 749 and a second part 756 including the second plurality of layers 748 and core 749. For example, the laser tool 752 may be applied to cut away the first part 754 and second part 756 until the release layer 722 is reached so that the first part 754 and second part 756 can be easily removed from the release layer 722. The release layer 722 is a substance other than prepeg or glue and is not intended to permanently bind the layers together. After cutting away the first part 754 and second part 756, a remaining part including the second plurality of layers 748 and core 749 (which is disposed between the first part 754 and second part 756) forms at least part of a pillar 758 which extends from the first plurality of layers 746. The pillar 758 may correspond to pillar 122, or any of pillars 122a′, 122b′, 122a″, and 122b″, for example. The pillar 758 may include the second plurality of layers 748, core 749 (e.g., similar to core 150 from FIG. 1), and one or more of the first plurality of layers 746. In some implementations, pillar 758 may include the second plurality of layers 748 and core 749 and none of the first plurality of layers 746.

In FIG. 7F at 760 the method includes finalizing the printed circuit board 762 (e.g., by removing any remaining portions of the release layer 722). The printed circuit board 762 includes the pillar 758 and upper board 764, for example, having a structure similar to the printed circuit board 100. However, in other embodiments the method of FIGS. 7A-7F may be modified to form a plurality of pillars from the structured core 712 (e.g., by applying the release layer to a plurality of locations with a plurality of locations being provided between locations of the release layer corresponding to locations of the pillars to be formed by using the laser tool 752). Though not shown in FIGS. 7A-7F, the method may further include coupling the pillar 758 to a main logic board (e.g., main logic board 370) to form a printed circuit board structure (e.g., printed circuit board structure 300). For example, the pillar 758 may be coupled to a main logic board by a gluing method (e.g., using epoxy, soldering, an underfill, or combinations thereof).

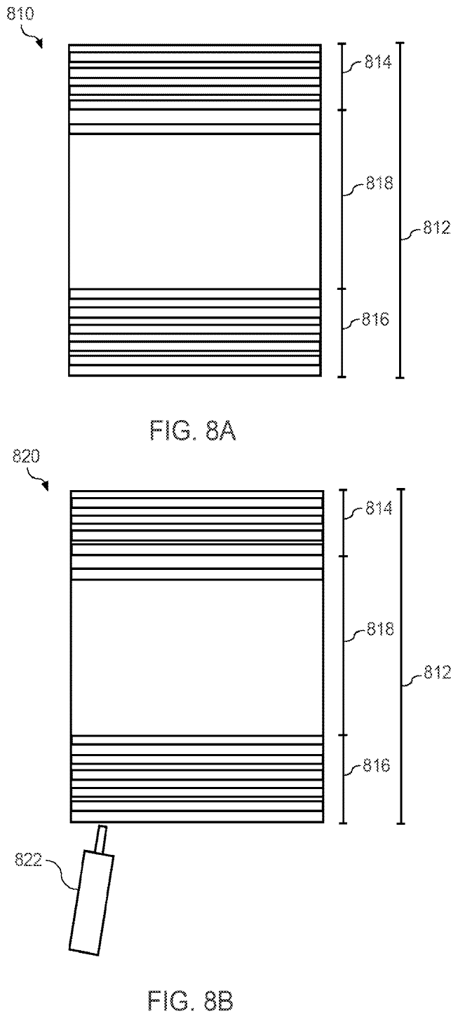

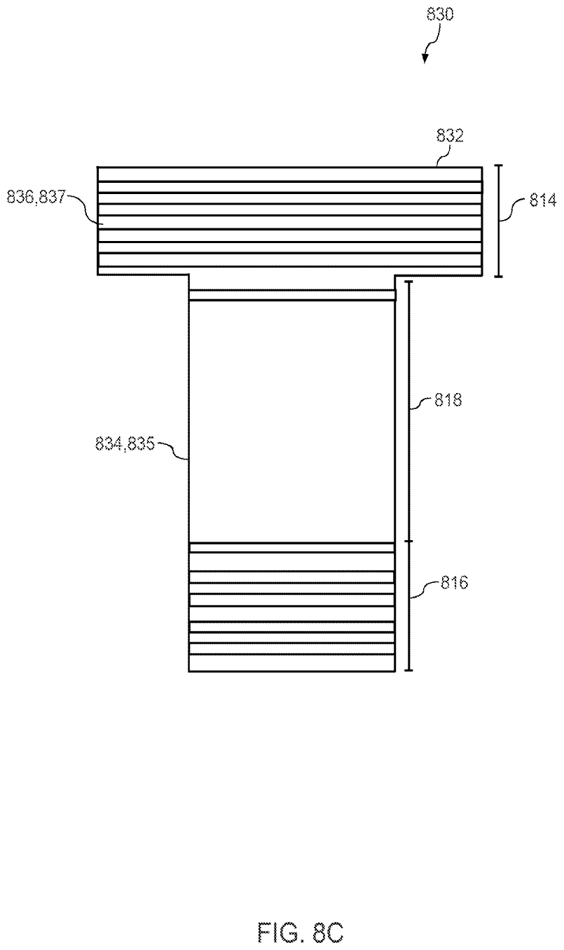

FIGS. 8A-8C depict an example method for manufacturing a printed circuit board through a milling process, according to one or more example embodiments of the disclosure.

In the example method, in FIG. 8A the method for manufacturing a printed circuit board structure includes at 810 providing a laminated structured core 812. The laminated structured core 812 may be similar to the laminated structured cores 644, 744. In some implementations, the laminated structured core 812 may not include a release layer. Referring to FIG. 8A, the laminated structure core 812 may include a first plurality of layers 814, a second plurality of layers 816, and a core 818.

The method further includes in FIG. 8B at 820 applying a milling tool 822 so as to cut away first and second parts including the second plurality of layers 816 and core 818, similar to that discussed above with respect to FIG. 6E. For example, the milling tool 822 may be applied to cut away the first and second parts until a release layer is reached so that the first and second parts can be easily removed. However, in some implementations a release layer may not be provided. Referring to FIG. 8C, after cutting away the first and second parts, a remaining part including the second plurality of layers 816 and core 818 (which was disposed between the first and second parts) forms at least part of a second portion 834 including pillar 835 which extends from a first portion 836 including an upper board 837 which includes the first plurality of layers 814. The pillar 835 may correspond to pillar 122, or any of pillars 122a′, 122b′, 122a″, and 122b″, for example. The pillar 835 may include the second plurality of layers 816, core 818 (e.g., similar to core 150 from FIG. 1), and one or more of the first plurality of layers 814. In some implementations, pillar 835 may include the second plurality of layers 816 and core 818 and none of the first plurality of layers 814. In some implementations, the method of FIGS. 8A-8C may be performed using a laser tool instead of a milling tool. The laser tool may be more precise than the milling tool, however the strength of the laser tool may be limited such that a height of a pillar obtainable using the laser tool may be less than a height of a pillar obtained using a milling tool.

Referring to FIG. 8C, a resulting printed circuit board 832 includes the first portion 836 having the upper board 837 and the second portion 834 having the pillar 835, for example, having a structure similar to the printed circuit board 100. However, in other embodiments the method of FIGS. 8A-8C may be modified to form a plurality of pillars from the laminated structured core 812. Though not shown in FIGS. 8A-8C, the method may further include coupling the pillar 835 to a main logic board (e.g., main logic board 370) to form a printed circuit board structure (e.g., printed circuit board structure 300). For example, the pillar 835 may be coupled to a main logic board by a gluing method (e.g., using epoxy, soldering, an underfill, or combinations thereof).

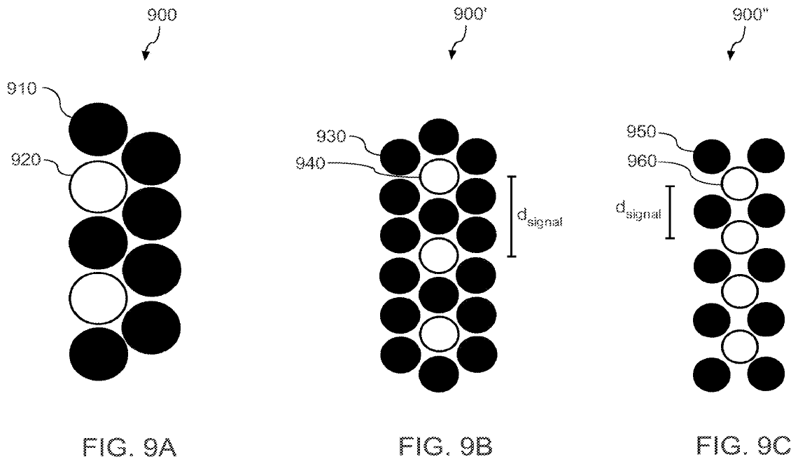

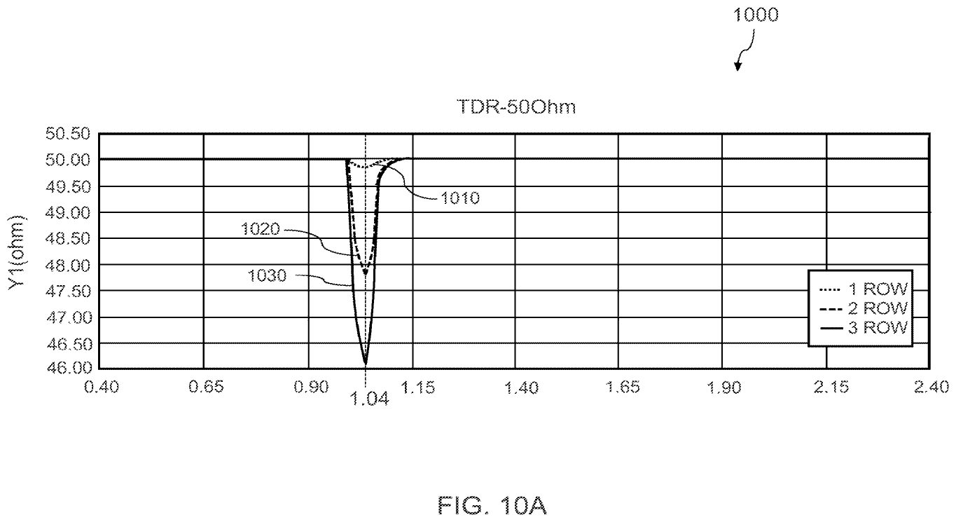

FIGS. 9A-9C depict example via configurations in a planar view, according to one or more example embodiments of the disclosure. As discussed above, the printed circuit board may include a plurality of vias. The via configurations shown in FIGS. 9A-9C may be implemented in any of the printed circuit boards disclosed herein (e.g., printed circuit boards 100, 400, 500, etc.). Referring to FIG. 9A, a first via configuration 900 includes a first row of vias including ground vias 910 provided on opposite sides of a signal via 920 and ground vias 910 provided in a second row. Referring to FIG. 9B, a second via configuration 900′ includes a first row of vias including ground vias 930 provided on opposite sides of a signal via 940 and ground vias 930 provided in second and third rows. Referring to FIG. 9C, a third via configuration 900″ includes a first row of vias including signal vias 960 and ground vias 950 provided in second and third rows. For example, a distance d_{signal} between adjacent signal vias 940 in the x-direction may be greater than a distance d′_{signal} between adjacent signal vias 960 in the x-direction. As example values, the distance d_{signal} may be about 1.3 mm and the distance d′_{signal} may be about 1.0 mm.

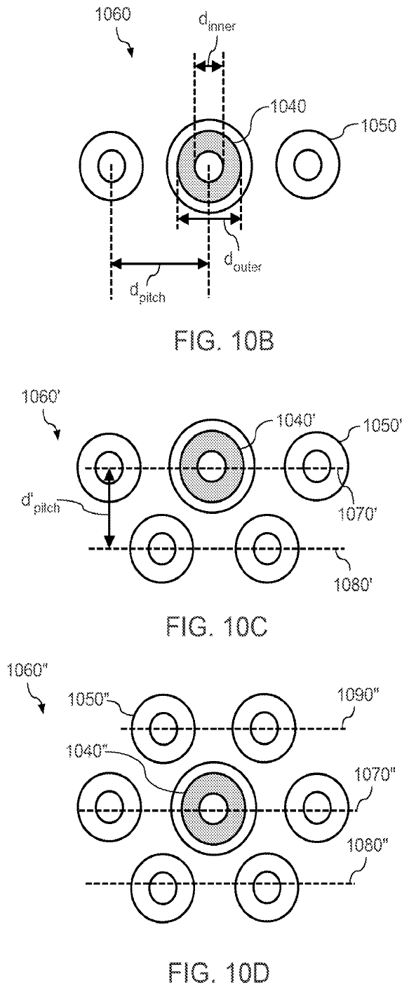

FIGS. 10A-10D relate to example impedance simulation results for various via configurations according to one or more example embodiments of the disclosure. According to the example printed board circuit structures disclosed herein (e.g., printed board circuit structures 300, 400, 500), vertical impedance control and signal stability/quality may be improved by virtue of the structure of the example printed circuit boards disclosed herein. For example, as will be explained with reference to FIGS. 10A-10D, a mismatch between an impedance value at a lower layer (e.g., at the main logic board) compared to an impedance value at an upper layer of the printed circuit board structure (e.g., at the upper board) is lower than compared to an impedance value mismatch of known connectors. For example, a configuration of vias including ground vias and a signal via which are arranged in one, two, or three rows, may have less than a 5 ohm deviation for a 50 ohm impedance value, which is an acceptable range for a 10% tolerance value. In contrast, known connectors have a limited pitch (e.g., a distance between vias being about 0.35 mm to about 0.40 mm), and thus ground vias are located closely to signal vias resulting in a reflection of the signal and causing degradation of the signal which may cause a logic error and/or a higher impedance mismatch between upper and lower layers.

Referring to FIG. 10A, impedance simulation results 1000 in which a 50 ohm impedance is applied to three via configurations are illustrated. For example, a first via configuration (shown in FIG. 10B) provides a first output 1010 of 49.83 ohms. For example, a second via configuration (shown in FIG. 10C) provides a second output 1020 of 47.78 ohms. For example, a third via configuration (shown in FIG. 10D) provides a third output 1030 of 46.08 ohms. Thus, in each case an impedance mismatch is less than 5 ohms, with each output satisfying a tolerance value of 10% (i.e., a mismatch less than 5 ohms when a 50 ohm impedance is applied).

Referring to FIG. 10B, the first via configuration 1060 includes a single row of vias including ground vias 1050 provided on opposite sides of a signal via 1040. In the example of FIG. 10B, the signal via 1040 has an inner diameter dinner and an outer diameter dₒᵤₜₑᵣ. A pitch (a distance between a center of the ground via 1050 and signal via 1040) corresponds to d_{pitch}. As example values, dᵢₙₙₑᵣ may be about 0.25 mm, dₒᵤₜₑᵣ may be about 0.45 mm, and d_{pitch} may be about 0.70 mm. Thus, a pitch according to the example embodiment may be greater than a pitch of known connectors. Accordingly, the ground vias are not located as closely to signal vias resulting in less reflection of the signal and improved signal integrity.

Referring to FIG. 10C, the second via configuration 1060′ includes a first row 1070′ of vias including ground vias 1050′ provided on opposite sides of a signal via 1040′ and ground vias 1050′ provided in a second row 1080′. In the example of FIG. 10C, a pitch (a distance between centers of the vias across rows) corresponds to d′_{pitch}. As an example value, d′_{pitch} may be about 0.50 mm. Thus, a pitch according to the example embodiment may be greater than a pitch of known connectors. Accordingly, the ground vias are not located as closely to signal vias resulting in less reflection of the signal and improved signal integrity.

Referring to FIG. 10D, the third via configuration 1060″ includes a first row 1070″ of vias including ground vias 1050″ provided on opposite sides of a signal via 1040″, ground vias 1050′ provided in a second row 1080″, and ground vias 1050″ provided in a third row 1090″. In the example of FIG. 10D, a pitch (a distance between centers of the vias) may be the same as in FIG. 10C. Thus, a pitch according to the example embodiment may be greater than a pitch of known connectors. Accordingly, the ground vias are not located as closely to signal vias resulting in less reflection of the signal and improved signal integrity.

According to the example embodiments disclosed herein, impedance control may be improved for high speed signals by configuring different signals/ground (GND) vias distributions vertically. As discussed above, in each of the different configurations, an impedance mismatch is less than 5 ohms, with each output satisfying a tolerance value of 10% (i.e., a mismatch less than 5 ohms when a 50 ohm impedance is applied). Accordingly, vertical signal integrity is improved in the printed circuit board disclosed herein.

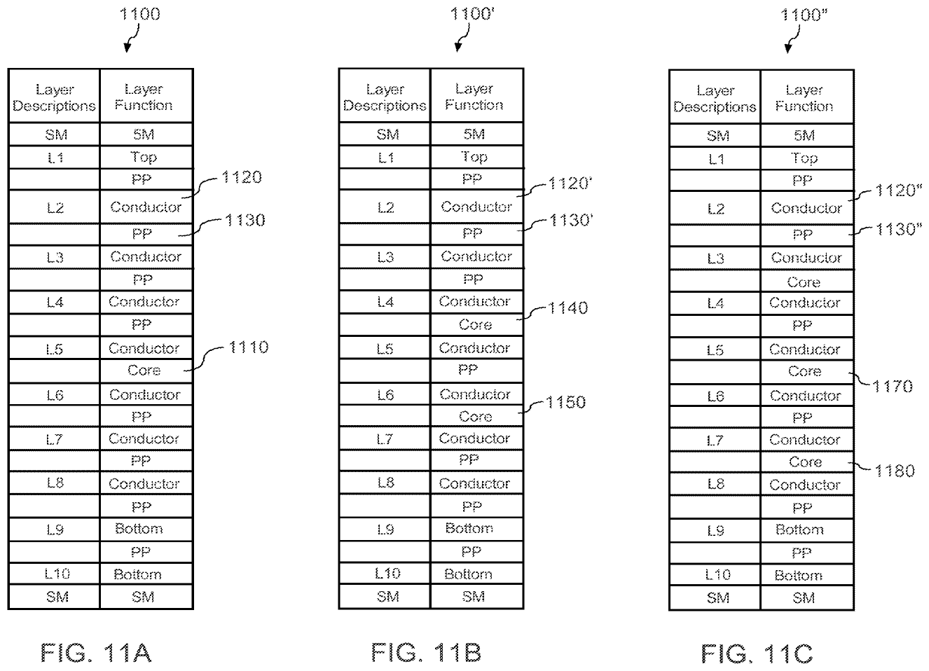

FIGS. 11A-11C depict example stacked layer structures of a printed circuit board, according to one or more example embodiments of the disclosure. The stacked layer structures shown in FIGS. 11A-11C may be implemented in any of the printed circuit boards disclosed herein (e.g., printed circuit boards 100, 400, 500, etc.). For example, in some embodiments, the printed circuit board can include ten or more layers. However, in alternative embodiments the printed circuit board can include less than ten layers.

Referring to FIG. 11A, an example printed circuit board 1100 includes a plurality of layers L1 through L10. For example, one or more of the layers L1 through L10 may include a top layer, a bottom layer, a conductor 1120 (e.g., a conductive material such as copper foil) and/or prepeg (PP) 1130 (e.g., insulative or dielectric materials). A solder mask (SM) may also be applied to each of the top and bottom layers. In FIG. 11A, a core 1110 is provided between layers L5 and L6. Generally, a thickness of the core 1110 is greater than a thickness of each layer.

Referring to FIG. 11B, an example printed circuit board 1100′ includes a plurality of layers L1 through L10. For example, one or more of the layers L1 through L10 may include a top layer, a bottom layer, a conductor 1120′ (e.g., a conductive material such as copper foil) and/or prepeg (PP) 1130′ (e.g., insulative or dielectric materials). A solder mask (SM) may also be applied to each of the top and bottom layers. In FIG. 11B, a first core 1140 is provided between layers L4 and L5 and a second core 1150 is provided between layers L6 and L7. Generally, a thickness of each of the first core 1140 and the second core 1150 is greater than a thickness of each layer.

Referring to FIG. 11C, an example printed circuit board 1100″ includes a plurality of layers L1 through L10. For example, one or more of the layers L1 through L10 may include a top layer, a bottom layer, a conductor 1120″ (e.g., a conductive material such as copper foil) and/or prepeg (PP) 1130″ (e.g., insulative or dielectric materials). A solder mask (SM) may also be applied to each of the top and bottom layers. In FIG. 11C, a first core 1160 is provided between layers L3 and L4, a second core 1170 is provided between layers L5 and L6, and a third core 1180 is provided between layers L7 and L8. Generally, a thickness of each of the first core 1160, second core 1170, and third core 1180 is greater than a thickness of each layer.

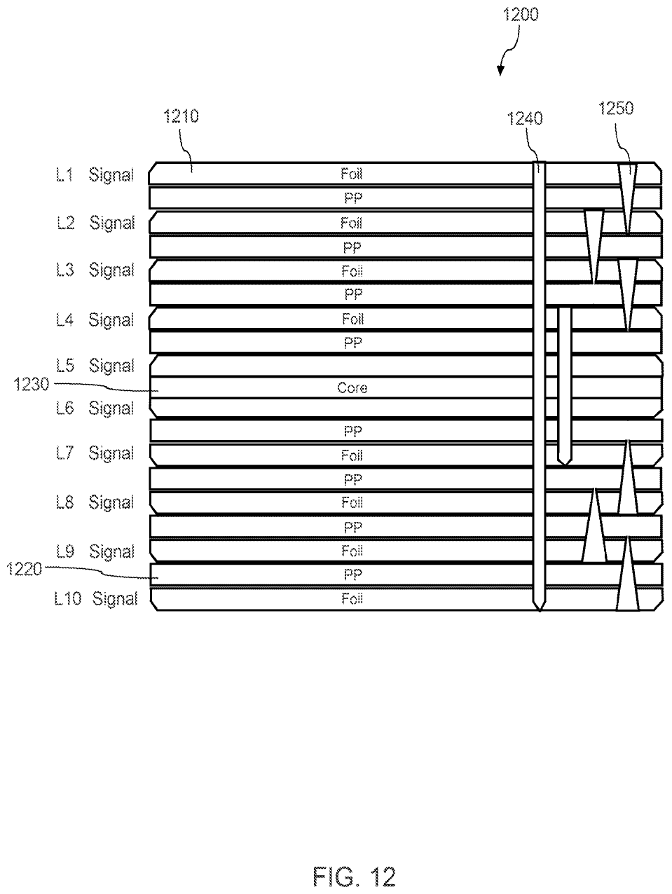

FIG. 12 depicts an example cross-section of a stacked layer structure of a printed circuit board, according to one or more example embodiments of the disclosure. The stacked layer structure shown in FIG. 12 may be implemented in any of the printed circuit boards disclosed herein (e.g., printed circuit boards 100, 400, 500, etc.). For example, in some embodiments, the printed circuit board can include ten or more layers. However, in alternative embodiments the printed circuit board can include less than ten layers.

Referring to FIG. 12, an example printed circuit board 1200 includes a plurality of layers L1 through L10. For example, one or more of the layers L1 through L10 may include a foil 1210 (e.g., a copper foil or other conductive material) and/or prepeg (PP) 1220 (e.g., insulative or dielectric materials). In FIG. 12, a core 1230 is provided between layers L5 and L6. Generally, a thickness of the core 1230 is greater than a thickness of each layer. The printed circuit board 1200 further includes a plurality of vias (e.g., via 1240 and via 1250).

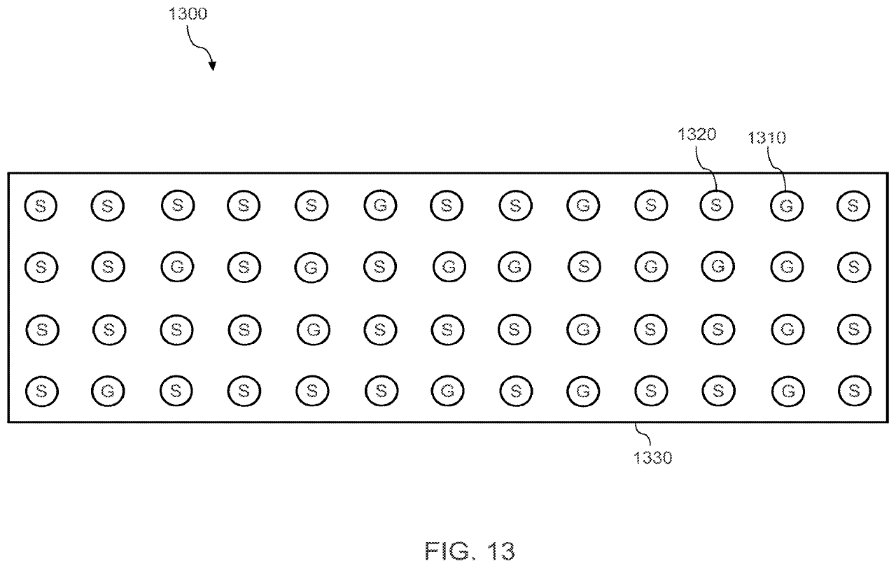

FIG. 13 depicts a planar view of an example pin array configuration of a printed circuit board, according to one or more example embodiments of the disclosure. According to the example embodiments of the disclosure, each pillar includes a plurality of pins which can be connected to a main logic board. For example, the plurality of pins may be greater than 50 pins. For example, the plurality of pins may be arranged at a bottom side or bottom face of the pillar facing the main logic board when the printed circuit board is coupled to the main logic board. Referring to FIG. 13, the plurality of pins are arranged in a plurality of rows, for example, four rows with thirteen pins in each row, on a bottom face 1330 of a pillar. The pins may be electrically connected to various components of an electronic device when the pillar is coupled to a main logic board to form a printed circuit board structure disposed inside the electronic device. For example, the pins may include a plurality of ground pins 1310 and a plurality of signal pins 1320. The disclosure is not limited to the example configuration of ground pins and signal pins shown in FIG. 13. For example, the ground pins and signal pins may be configured differently (e.g., a signal pin may be replaced by a ground pin and vice versa). The signal pins 1320 may serve as, for example, a mobile industry processor interface (MIPI), a quad serial peripheral interface (QSPI), Power nets, and the like. In contrast to the example configuration of pins as disclosed herein, known B2B connectors with more than 50 pins may only have two rows, with twenty-six pins in each row; resulting in a length of the B2B connector being longer compared to the pillar disclosed herein. For example, a B2B connector having 52 pins with a pitch of 0.35 mm between pins has a length of about 11.35 mm and a B2B connector having 52 pins with a pitch of 0.40 mm between pins has a length of about 12.60 mm. In contrast, according to an example embodiment a length of the pillar having 52 pins arranged in an array of four rows with thirteen pins in each row, has a length of about 8 mm to about 9 mm (e.g., about 8.8 mm), which is a reduction in length compared to the B2B connectors of about 23% and 30%, respectively.

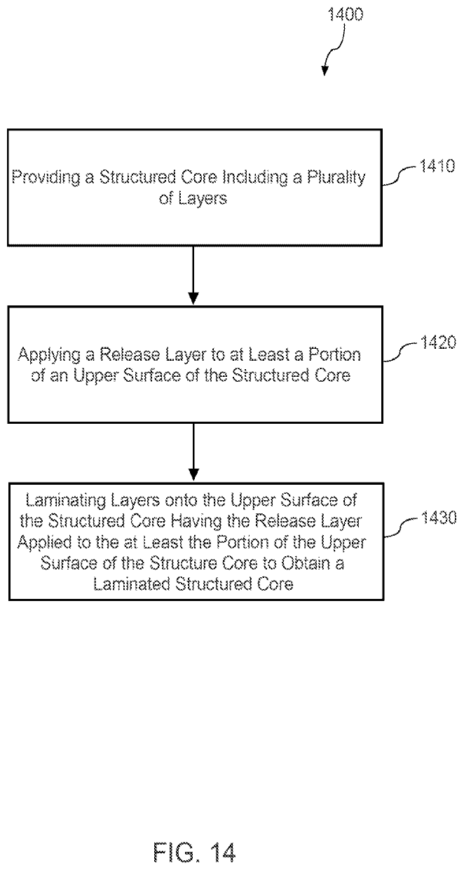

FIG. 14 illustrates a flow diagram of an example, non-limiting method for manufacturing a laminated structure core, according to one or more example embodiments of the disclosure. Referring to FIG. 14, the method 1400 includes operations similar to those discussed herein with respect to FIG. 6A through FIG. 7F. At 1410, the method includes providing a structured core (e.g., structured cores 612, 712) including a plurality of layers (e.g., layers 614, 714). At 1420, the method 1400 includes applying a release layer (e.g., release layers 622, 722) to at least a portion of an upper surface (e.g., upper surfaces 624, 724) of the structured core. At 1430, the method 1400 includes laminating layers (e.g., layers 632, 642, 732, 742) onto the upper surface of the structured core having the release layer applied to the at least the portion of the upper surface of the structure core to obtain a laminated structured core (e.g., laminated structured cores 644, 744).

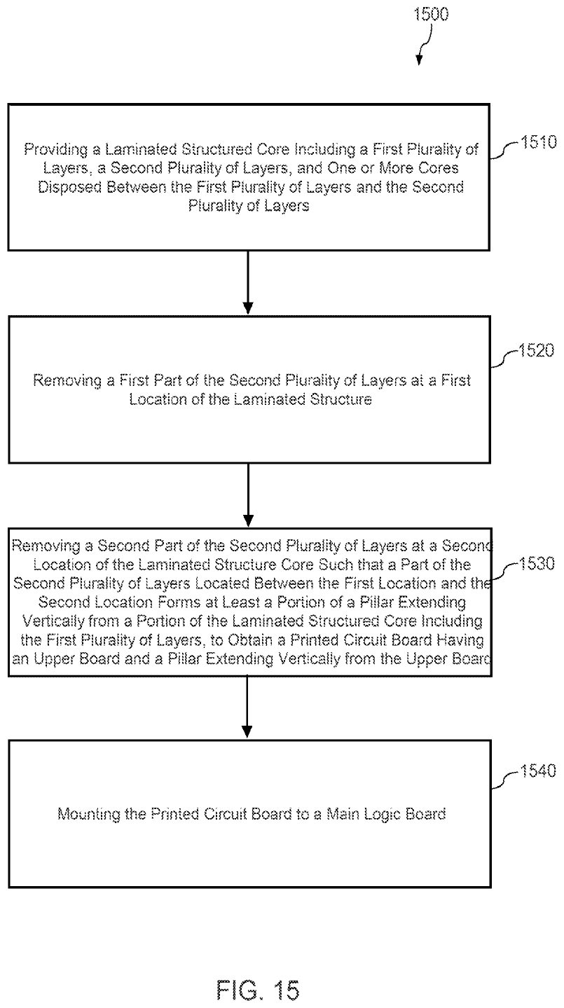

FIG. 15 illustrates a flow diagram of an example, non-limiting method for manufacturing a printed circuit board, according to one or more example embodiments of the disclosure. Referring to FIG. 15, the method 1500 includes operations similar to those discussed herein with respect to FIG. 6A through FIG. 8C. For example, at 1510 the method 1500 for manufacturing a printed circuit board structure includes providing a laminated structured core (e.g., laminated structured cores 644, 744, 812) including a first plurality of layers (e.g., first plurality of layers 646, 846, 814), a second plurality of layers (e.g., second plurality of layers 648, 848, 816), and one or more cores (e.g., one or more cores 649, 749, 818) disposed between the first plurality of layers and the second plurality of layers. At 1520, the method 1500 includes removing a first part of the second plurality of layers at a first location of the laminated structure core. At 1530, the method 1500 includes removing a second part of the second plurality of layers at a second location of the laminated structure core. For example, the first part of the second plurality of layers and the second part of the second plurality of layers may be removed by a mechanical milling process or a de-cap cutting process. For example, each of the first part and the second part of the second plurality of layers may be removed through a de-cap process by applying the milling tool or the laser so as to cut away the first and second parts of the second plurality of layers until the release layer is reached. The first and second parts are removed such that a part of the second plurality of layers located between the first location and the second location forms at least a portion of a pillar extending vertically from a portion of the laminated structured core including the first plurality of layers, to obtain a printed circuit board having an upper board and a pillar extending vertically from the upper board. At operation 1540, the method 1500 includes mounting the printed circuit board to a main logic board. For example, one or more pillars of the printed circuit board may be mounted to the main logic board by a gluing method (e.g., using epoxy, soldering, an underfill, or combinations thereof).

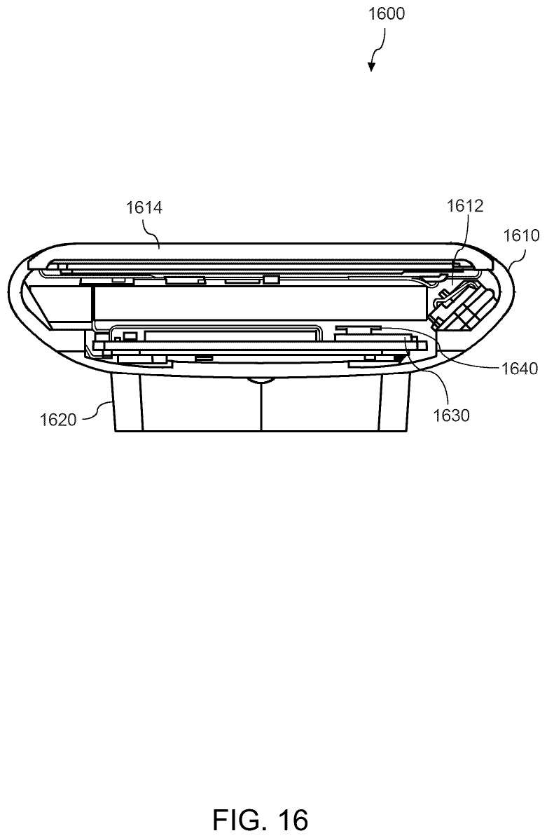

FIG. 16 depicts an example view of an electronic device having a printed circuit board structure according to one or more example embodiments of the disclosure. Referring to FIG. 16, electronic device 1600 corresponds to a wearable computing device which can be worn, for example, on an arm (e.g., wrist) of a user. A band 1620 may be used to secure the electronic device 1600 to the arm (e.g., wrist) of the user. For example, the electronic device 1600 can include a body 1610 having a cavity 1612 in which one or more electronic components are disposed (e.g., disposed on one or more printed circuit boards). The electronic device 1600 can include a cover 1614, for example to protect a display of the electronic device 1600 from being scratched or damaged. For example, the electronic device 1600 can include a printed circuit board 1640 disposed within the cavity 1612 of the body 1610. For example, the printed circuit board 1640 may be mounted on a main logic board 1630 and may correspond to any of the printed circuit boards disclosed herein. Furthermore, one or more electronic components can be disposed on the printed circuit board 1640. The electronic device 1600 can further include one or more batteries and one or more sensors (not shown) that are disposed within the cavity 1612 defined by the body 1610. The electronic device 1600 may be a device other than a wearable computing device, such as a smartphone, a tablet, a laptop, a camera, and the like.

Each block of the flowchart illustrations may represent a unit, module, segment, or portion of code, which comprises one or more executable instructions for implementing the specified logical function(s). It should also be noted that in some alternative implementations, the functions noted in the blocks may occur out of order. For example, two blocks shown in succession may in fact be executed substantially concurrently (simultaneously) or the blocks may sometimes be executed in the reverse order, depending upon the functionality involved.

While the disclosure has been described with respect to various example embodiments, each example is provided by way of explanation, not limitation of the disclosure. Those skilled in the art, upon attaining an understanding of the foregoing, can readily produce alterations to, variations of, and equivalents to such embodiments. Accordingly, the disclosure does not preclude inclusion of such modifications, variations and/or additions to the disclosed subject matter as would be readily apparent to one of ordinary skill in the art. For example, features illustrated or described as part of one embodiment can be used with another embodiment to yield a still further embodiment. Thus, it is intended that the disclosure covers such alterations, variations, and equivalents.

What is claimed is:

1. A printed circuit board, comprising:
a first portion including an upper board having a first width in a widthwise direction of the upper board; and
a second portion, integrally formed with the first portion as a single body, the second portion including one or more pillars extending vertically from the first portion and disposed between a first end of the upper board and a second end of the upper board in the widthwise direction, wherein each of the one or more pillars has a second width in the widthwise direction which is narrower than the first width.

2. The printed circuit board of claim 1, wherein the one or more pillars include a pillar disposed at a central portion of the upper board in the widthwise direction.

3. The printed circuit board of claim 1, wherein the second portion includes a plurality of pillars including a first pillar disposed adjacent to the first end of the upper board and a second pillar disposed adjacent to the second end of the upper board.

4. The printed circuit board of claim 3, wherein the plurality of pillars include a third pillar disposed between the first pillar and the second pillar in a central portion of the upper board in the widthwise direction.

5. The printed circuit board of claim 4, wherein
the printed circuit board is coupleable to a main logic board such that when the printed circuit board is coupled to the main logic board, the first pillar is coupled to the main logic board at an angle which is oblique to the second pillar, and the first and second pillars are coupled to the main logic board at respective angles which are oblique to the third pillar.

6. The printed circuit board of claim 1, wherein
a vertical height of each of the one or more pillars from an end of the pillar which extends vertically from the first portion to a distal end of the pillar, is less than or equal to about 3.0 mm.

7. The printed circuit board of claim 1, wherein the printed circuit board includes at least ten layers, the upper board including at least four layers of the at least ten layers, and the one or more pillars including at least six layers of the at least ten layers.

8. The printed circuit board of claim 1, wherein
a distal end of each of the one or more pillars includes at least fifty pins, and
the second width is less than about 9 mm.

9. An electronic device, comprising:
a body; and
a printed circuit board structure disposed within the body, including:
a main logic board, and
a printed circuit board, including:
a first portion including an upper board having a first width in a widthwise direction of the upper board, and
a second portion, integrally formed with the first portion as a single body, the second portion including one or more pillars, coupled to the main logic board, extending vertically between the main logic board and the first portion and disposed between a first end of the upper board and a second end of the upper board in the widthwise direction, wherein each of the one or more pillars has a second width in the widthwise direction which is narrower than the first width.

10. The electronic device of claim 9, wherein the one or more pillars include a pillar disposed at a central portion of the upper board in the widthwise direction.

11. The electronic device of claim 9, wherein the second portion includes a plurality of pillars including a first pillar disposed adjacent to the first end of the upper board and a second pillar disposed adjacent to the second end of the upper board.

12. The electronic device of claim 11, wherein the plurality of pillars include a third pillar disposed between the first pillar and the second pillar in a central portion of the upper board in the widthwise direction.

13. The electronic device of claim 12, wherein
the first pillar is coupled to the main logic board at an angle which is oblique to the second pillar, and
the first and second pillars are coupled to the main logic board at respective angles which are oblique to the third pillar.

14. The electronic device of claim 9, wherein a vertical height of each of the one or more pillars, extending from the main logic board to the first portion, is less than or equal to about 3.0 mm.

15. A method for manufacturing a printed circuit board structure, comprising:
providing a laminated structured core including a first plurality of layers, a second plurality of layers, and one or more cores disposed between the first plurality of layers and the second plurality of layers;
removing a first part of the second plurality of layers at a first location of the laminated structure core; and
removing a second part of the second plurality of layers at a second location of the laminated structure core such that a part of the second plurality of layers located between the first location and the second location forms at least a portion of a pillar extending vertically from a portion of the laminated structured core including the first plurality of layers.

16. The method for manufacturing the printed circuit board structure of claim 15, wherein providing the laminated structured core comprises:
providing a structured core including the first plurality of layers;
applying a release layer to at least a portion of an upper surface of the structured core; and
laminating the second plurality of layers onto the upper surface of the structured core having the release layer applied to the at least the portion of the upper surface of the structure core to obtain the laminated structured core.

17. The method for manufacturing the printed circuit board structure of claim 15, wherein removing the first part of the second plurality of layers at the first location of the laminated structure core and removing the second part of the second plurality of layers at the second location of the laminated structure core, is performed by a mechanical milling process or a de-cap process.

18. The method for manufacturing the printed circuit board structure of claim 16, wherein each of the first part of the second plurality of layers and the second part of the second plurality of layers extend to the release layer.

19. The method for manufacturing the printed circuit board structure of claim 15, further comprising coupling the pillar to a main logic board.

20. The method for manufacturing the printed circuit board structure of claim 19, wherein a vertical height of the pillar, which extends from the main logic board to the portion of the laminated structured core including the first plurality of layers, is less than or equal to about 3.0 mm.
